(19) United States
(12) Patent Application Publication
(10) Pub. No.: US 2016/0343889 A1
(43) Pub. Date: Nov. 24, 2016

(54) SOLAR CELL

(71) Applicant: Panasonic Intellectual Property Management Co., Ltd., Osaka (JP)

(72) Inventor: Takahiro MISHIMA, Hyogo (JP)

(73) Assignee: Panasonic Intellectual Property Management Co., Ltd., Osaka (JP)

(21) Appl. No.: 15/227,968

(22) Filed: Aug. 4, 2016

Related U.S. Application Data
(63) Continuation of application No. PCT/JP2014/079474, filed on Nov. 6, 2014.

(30) Foreign Application Priority Data
Feb. 6, 2014 (JP) 2014-021070

(51) Int. Cl. H01L 31/0224; H01L 31/0376; H01L 31/0352

(52) U.S. Cl. CPC H01L 31/022458; H01L 31/03529; H01L 31/03762

(57) ABSTRACT

A solar cell is provided which includes: a photoelectric converter having a p-type surface on a major surface and an n-type surface on the major surface; a p-side electrode disposed on the p-type surface and formed from a plating film; an n-side electrode disposed on the n-type surface and formed from a plating film; a p-side seed layer disposed between the p-type surface and the p-side electrode; and an n-side seed layer disposed between the n-type surface and the n-side electrode, wherein a width W₁ between the two closest points of the p-side electrode and the n-side electrode that are adjacent one another is greater than a width W₂ between the two closest points of an end of the p-side seed layer and an end of the n-side seed layer that are adjacent one another.

### CROSS REFERENCE TO RELATED APPLICATIONS

This application is a U.S. continuation application of PCT

International Patent Application Number PCT/JP2014/079474 filed on Nov. 6, 2014, claiming the benefit of priority of Japanese Patent Application Number 2014-021070 filed on Feb. 6, 2014, the entire contents of which are hereby incorporated by reference.

### TECHNICAL FIELD

The present disclosure relates to a back contact solar cell.

### BACKGROUND ART

Conventionally, a back contact solar cell is known as a solar cell having improved photoelectric conversion efficiency (for example, see WO2013/081104).

### SUMMARY

Increasing collection efficiency is desired in a back contact solar cell.

One object of the present disclosure is to provide a solar cell capable of increasing collection efficiency.

According to one aspect of the present disclosure, a solar cell includes: a photoelectric converter having a p-type surface on a major surface and an n-type surface on the major surface; a p-side electrode disposed on the p-type surface and formed from a plating film; an n-side electrode disposed on the n-type surface and formed from a plating film; a p-side seed layer disposed between the p-type surface and the p-side electrode; and an n-side seed layer disposed between the n-type surface and the n-side electrode, wherein a width W1 between two closest points of the p-side electrode and the n-side electrode that are adjacent one another is greater than a width W2 between two closes points of an end of the p-side seed layer and an end of the n-side seed layer that are adjacent one another.

Accordingly, collection efficiency can be increased.

### BRIEF DESCRIPTION OF THE DRAWINGS

The figures depict one or more implementations in accordance with the present teaching, by way of examples only, not by way of limitations. In the figures, like reference numerals refer to the same or similar elements.

FIG. 1 is a schematic plan view of a solar cell according to Embodiment 1.

FIG. 2 is a schematic cross sectional view of the solar cell according to Embodiment 1.

FIG. 3 is an enlarged schematic cross sectional view of the vicinity of the insulating layer in the solar cell according to Embodiment 1.

FIG. 4 is an enlarged schematic cross sectional view of the vicinity of the insulating layer in the solar cell according to Embodiment 2.

FIG. 5 is an enlarged schematic cross sectional view of the vicinity of the insulating layer in the solar cell according to Embodiment 3.

### DETAILED DESCRIPTION

The following describes preferred embodiments. The embodiments are purely illustrative, and are not intended to limit the scope of the present disclosure. In the drawings, elements having essentially the same function may share like reference numbers.

### Embodiment 1

### Solar Cell 1a Configuration

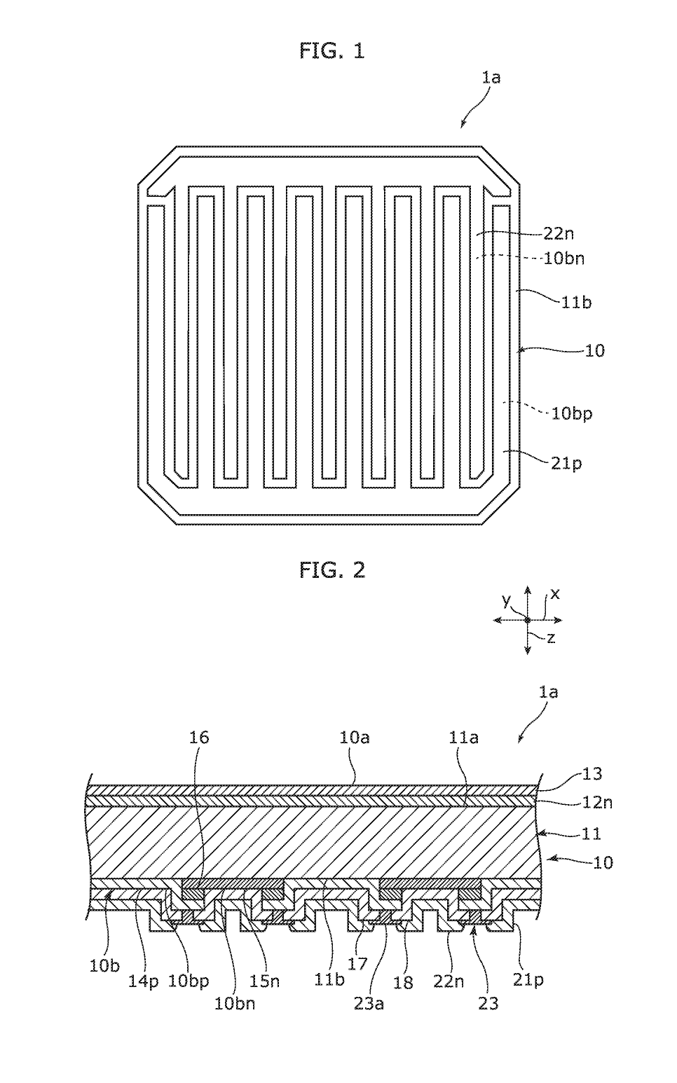

FIG. 1 is a schematic plan view of a solar cell 1a according to Embodiment 1. FIG. 2 is a schematic cross sectional view of the solar cell 1a according to Embodiment 1. As illustrated in FIG. 1 and FIG. 2, the solar cell 1a includes a photoelectric converter 10. The photoelectric converter 10 includes a substrate 11, and the substrate 11 has a first major surface 11a and a second major surface 11b. The first major surface 11a forms a light receiving surface 10a, and the second major surface 11b is the back surface. Here, the “light receiving surface” is the surface that mainly receives light.

The photoelectric converter 10 is a component that generates carriers such as electron holes and electrons upon receiving light. Note that the photoelectric converter 10 may generate carriers only upon receiving light at the first major surface 11a that forms the light receiving surface 10a, and, alternatively, may generate carriers upon receiving light at the second major surface 11b functioning as the back surface in addition to the first major surface 11a.

The photoelectric converter 10 includes, on the second major surface 11b, a semiconductor layer 14p and a semiconductor layer 15n. A p-side electrode 21p is disposed above the p-type surface 10bp. An n-side electrode 22n is disposed on the n-type surface 10bn. The p-side electrode 21p and n-side electrode 22n are comb-shaped and disposed so as to be interdigitated with each other. More specifically, the p-side electrode 21p and the n-side electrode 22n each include a plurality of fingers and a bus bar that electrically connects the plurality of fingers. The configuration of the electrodes is not particularly limited in this embodiment. For example, the electrodes may be configured of a plurality of fingers only.

The photoelectric converter 10 includes, for example, a substrate including a semiconductor material, a p-type semiconductor layer having the p-type surface 10bp and disposed on a major surface of the substrate, and a n-type semiconductor layer having the n-type surface 10bn and disposed on the major surface of the substrate. The p-type surface 10bp may include a p-type dopant diffusion region provided on the substrate. The n-type surface 10bn may include an n-type dopant diffusion region provided on the substrate.

The first major surface 11a that forms the light receiving surface 10a has an uneven surface. The uneven surface may be a textured surface. Here, a “textured surface” is an uneven surface that inhibits rear surface reflection and increases the amount of light absorbed by the photoelectric converter. One example of a textured surface is a pyramid-shaped (quadrangular pyramid, truncated quadrangular pyramid) uneven surface formed by anisotropic etching the rear surface of a monocrystalline silicon substrate including a (100) surface.

As illustrated in FIG. 2, the solar cell 1a includes a photoelectric converter 10 having the light receiving surface 10a and a back surface 10b. The photoelectric converter 10 includes a substrate 11. The substrate 11 includes a semiconductor material. The substrate 11 may include, for example, a crystalline semiconductor such as crystalline silicon. The substrate 11 has one conductivity type. More specifically, in this embodiment, the substrate 11 is exemplified as having an n-type conductivity.

A semiconductor layer 12n is provided on the first major surface 11a, which is on the light receiving surface 10a side of the substrate 11, and the semiconductor layer 12n includes a semiconductor having the same conductivity type (n-type) as the substrate 11. The semiconductor layer 12n covers essentially the entire first major surface 11a. The semiconductor layer 12n includes, for example, an n-type amorphous silicon. The semiconductor layer 12n has a thickness approximately in a range from 1 nm to 10 nm, for example.

Note that a semiconductor layer including a substantially intrinsic i-type semiconductor and having a thickness of a degree that does not substantially affect power generation (for example, a thickness approximately in a range from a few angstroms to 250 angstroms) may be provided between the semiconductor layer 12n and the first major surface 11a.

A reflection inhibiting layer 13 that functions both to inhibit reflection and as a protective film is disposed on the semiconductor layer 12n, more specifically, on its rear surface which faces away from the substrate 11. The reflection inhibiting layer 13 forms the light receiving surface 10a of the photoelectric converter 10. The reflection inhibiting layer 13 may include, for example, silicon nitride.

Note that the thickness of the reflection inhibiting layer 13 is determined in accordance with, for example, the wavelength of the light whose reflection the reflection inhibiting layer 13 is to inhibit. The thickness of the reflection inhibiting layer 13 is approximately in a range from 50 nm to 200 nm, for example.

A semiconductor layer 14p including a semiconductor having a different conductivity type than the substrate 11 (i.e., having a p-type conductivity) is provided on part of the second major surface 11b of the substrate 11. A semiconductor layer 15n including a semiconductor having the same conductivity type as the substrate 11 (i.e., having an n-type conductivity) is provided on the second major surface 11b of the substrate 11, in at least part of the area in which the semiconductor layer 14p is not provided. In this embodiment, the semiconductor layer 12n covers essentially the entire first major surface 11a. The semiconductor layer 14p includes a p-type amorphous silicon, and the semiconductor layer 15n includes an n-type amorphous silicon.

The semiconductor layer 14p and the semiconductor layer 15n form the back surface 10b of the photoelectric converter 10. The semiconductor layer 14p forms the p-type surface 10bp. The semiconductor layer 15n forms the n-type surface 10bn.

The semiconductor layer 14p has a thickness approximately in a range from 2 nm to 20 nm, for example. The semiconductor layer 15n has a thickness approximately in a range from 5 nm to 50 nm, for example. Note that a semiconductor layer including a substantially intrinsic i-type semiconductor and having a thickness of a degree that does not substantially affect power generation (for example, a thickness approximately in a range from a few angstroms to 250 angstroms) may be provided between the semiconductor layer 14p and the second major surface 11b. Similarly, a semiconductor layer including a substantially intrinsic i-type semiconductor and having a thickness of a degree that does not substantially affect power generation (for example, a thickness approximately in a range from a few angstroms to 250 angstroms) may be provided between the semiconductor layer 15n and the second major surface 11b. Such a semiconductor layer including a substantially intrinsic i-type semiconductor may include, for example, an amorphous silicon.

The x-axis ends of the semiconductor layer 14p overlap with the semiconductor layer 15n in the thickness direction extending along the z axis. An insulating layer 16 is disposed between the x axis ends of the semiconductor layer 14p and the semiconductor layer 15n. The insulating layer 16 may include, for example, silicon nitride or silicon oxide.

A p-side seed layer 17 is disposed on the semiconductor layer 14p. The p-side seed layer 17 functions as a seed for forming the p-side electrode 21p by a plating process. An n-side seed layer 18 is disposed on the semiconductor layer 15n. The n-side seed layer 18 functions as a seed for forming the n-side electrode 22n by a plating process.

The p-side electrode 21p, which collects electron holes, is disposed on the p-side seed layer 17 provided on the p-type surface 10bp. The p-side electrode 21p is electrically connected to the p-type surface 10bp via the p-side seed layer 17. The n-side electrode 22n, which collects electrons, is disposed on the n-side seed layer 18 provided on the n-type surface 10bn. The n-side electrode 22n is electrically connected to the n-type surface 10bn via the n-side seed layer 18. In other words, the p-side seed layer 17 and the n-side seed layer 18 are electrically conductive.

The p-side electrode 21p and the n-side electrode 22n are each formed from a plating film. Note that the p-side electrode 21p and the n-side electrode 22n may each have a layered structure including a plurality of plating film layers. More specifically, the p-side electrode 21p and the n-side electrode 22n may each have a layered structure including a first plating film containing Cu and a second plating film containing Sn.

The p-side electrode 21p and the n-side electrode 22n each have a thickness approximately in a range from 20 μm to 50 μm, for example.

In a surface direction of the back surface 10b of the photoelectric converter 10 (i.e., in the x axis direction), an insulating layer 23 is disposed between adjacent ends of the p-side seed layer 17 and the n-side seed layer 18.

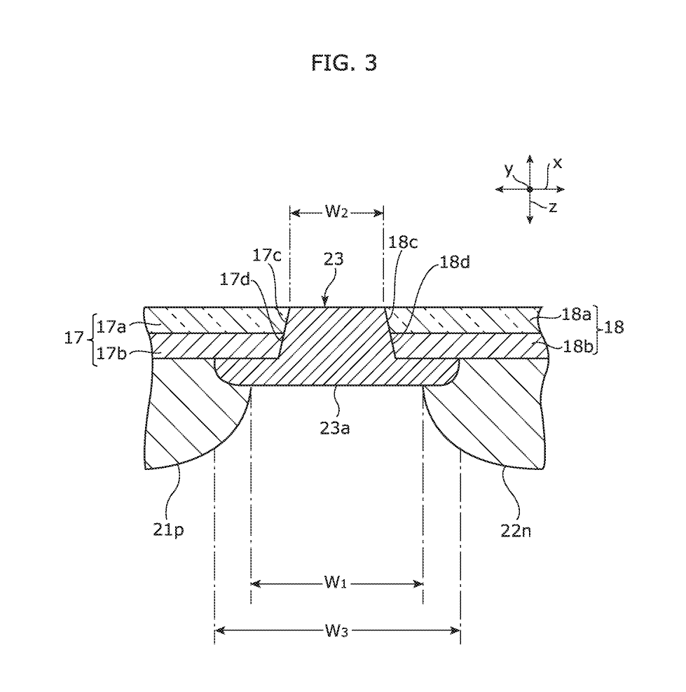

FIG. 3 is an enlarged schematic cross sectional view of the vicinity of the insulating layer in the solar cell according to Embodiment 1. As illustrated in FIG. 3, in this embodiment, the p-side seed layer 17 has a layered structure including a transparent conducting layer 17a and a metal layer 17b. Similarly, the n-side seed layer 18 has a layered structure including a transparent conducting layer 18a and a metal layer 18b. Thus, the p-side seed layer 17 includes the transparent conducting layer 17a disposed on the p-type surface 10bp (refer to FIG. 2), and the metal layer 17b disposed on the transparent conducting layer 17a. Similarly, the n-side seed layer 18 includes the transparent conducting layer 18a disposed on the n-type surface 10bn (refer to FIG. 2), and the metal layer 18b disposed on the transparent conducting layer 18a.

FIG. 3 is an enlarged schematic cross sectional view of the vicinity of the insulating layer in the solar cell according to Embodiment 1. As illustrated in FIG. 3, in this embodiment, the p-side seed layer 17 has a layered structure including a transparent conducting layer 17a and a metal layer 17b. Similarly, the n-side seed layer 18 has a layered structure including a transparent conducting layer 18a and a metal layer 18b. Thus, the p-side seed layer 17 includes the transparent conducting layer 17a disposed on the p-type surface 10bp (refer to FIG. 2), and the metal layer 17b disposed on the transparent conducting layer 17a. Similarly, the n-side seed layer 18 includes the transparent conducting layer 18a disposed on the n-type surface 10bn (refer to FIG. 2), and the metal layer 18b disposed on the transparent conducting layer 18a.

In this embodiment, the transparent conducting layer 17a and the metal layer 17b are formed such that the end 17d of metal layer 17b is located roughly in the same x axis position as the end 17c of transparent conducting layer 17a. Similarly, the transparent conducting layer 18a and the metal layer 18b are formed such that the end 18d of metal layer 18b is located roughly in the same x axis position as the end 18c of transparent conducting layer 18a.

In this embodiment, the p-side seed layer 17 includes two film layers (the transparent conducting layer and the metal layer) made of different materials. When the p-side seed layer 17 including the transparent conducting layer and the metal layer is to be patterned by etching using a resist film after the p-side seed layer 17 is formed, it is possible to adjust the individual etching amounts for the transparent conducting layer and the metal layer by selecting particular etching liquids and changing the etching time, etc. When the etching amount of the metal layer is greater than that of the transparent conducting layer, the width of the transparent conducting layer can be increased beyond that of the metal layer. However, by using other etching conditions, the metal layer and the transparent conducting layer can be made to have roughly the same widths, and, alternatively, the width of the metal layer can be increased beyond that of the transparent conducting layer.

In this embodiment, the x axis position of the end of the p-side seed layer 17 is defined by the position of the end 17c of the transparent conducting layer 17a. Similarly, the x axis position of the end of the n-side seed layer 18 is defined by the position of the end 18c of the transparent conducting layer 18a. Thus, the width W₂ between the end of the p-side seed layer 17 and the end of the n-side seed layer 18 is defined as the width between the two closest points of the p-side seed layer 17 and the n-side seed layer 18.

The transparent conducting layer 17a and the transparent conducting layer 18a include, for example, a transparent conducting oxide such as indium tin oxide (ITO). The metal layer 17b and the metal layer 18b include, for example, at least one type of metal such as Cu or Ag. The transparent conducting layer 17a and the transparent conducting layer 18a have a thickness approximately in a range from 0.1 μm to 1.0 μm, for example. The metal layer 17b and the metal layer 18b have a thickness approximately in a range from 0.1 μm to 1.0 μm, for example. Note that in this embodiment, the p-side seed layer 17 and the n-side seed layer 18 each have a layered structure including a transparent conducting layer and a metal layer, but the p-side seed layer 17 and the n-side seed layer 18 may each include only a transparent conducting layer, and, alternatively, may each include only a metal layer.

In this embodiment, the head 23a of insulating layer 23 forms the back surface of the insulating layer 23, and extends so as to cover the end 17d of the p-side seed layer 17 and the end 18d of the n-side seed layer 18. The p-side electrode 21p is disposed on the p-side seed layer 17. The n-side electrode 22n is disposed on the n-side seed layer 18. The p-side electrode 21p is formed so as to cover a portion of the head 23a of the insulating layer 23. The n-side electrode 22n is also formed so as to cover a portion of the head 23a of the insulating layer 23. Thus, the head 23a of the insulating layer 23 is embedded between the p-side seed layer 17 and the p-side electrode 21p as well as between the n-side seed layer 18 and the n-side electrode 22n.

The insulating layer 23 preferably includes an inorganic insulating material such as silicon oxide or silicon nitride, and an organic insulating material such as epoxy resin, acrylic resin, or urethane resin. The insulating layer 23 preferably includes a resist material containing epoxy resin in particular.

As illustrated in FIG. 3, in this embodiment, in a cross section (zx plane) of the p-side electrode 21p and the n-side electrode 22n finger electrodes taken perpendicular to the lengthwise direction of the finger electrodes (y axis direction), the width W₁ between the two closest points of the p-side electrode 21p and the n-side electrode 22n that are adjacent one other is greater than the width W₂ between the two closest points of the ends of the p-side seed layer 17 and the n-side seed layer 18 that are adjacent one another. Thus, the width W₂ can be made to be relatively narrower than the width W₁. As a result, the surface area of the p-side seed layer 17 and the n-side seed layer 18 in the solar cell 1a can be made to be relatively larger, whereby collection efficiency can be increased.

Note that the width W₁ is preferably in a range from 10 μm to 1000 μm, and more preferably in a range from 30 μm to 300 μm. Note that the width W₂ is preferably in a range from 1 μm to 100 μm, and more preferably in a range from 1 μm to 20 μm.

The width W₃ of the head 23a of the insulating layer 23 in the extending direction of the head 23a (x axis direction) is approximately equal to the sum of (i) two times the thickness of the p-side electrode 21p or n-side electrode 22n and (ii) the width W₁, is preferably greater than or equal two times the width W₂, and more preferably greater than or equal to ten times the width W₂. Increasing the width W₃ makes it possible to increase the width W₁. Thus, by increasing the width W₃, short circuits between the p-side electrode 21p and the n-side electrode 22n can be more assuredly prevented. However, if the width W₃ is too wide, the width W₁ also becomes too wide, whereby the surface area of the solar cell covered by the p-side electrode 21p and the n-side electrode 22n is small. When the width W₃ is increased without changing the thickness of the p-side electrode 21p and the n-side electrode 22n, the electrical resistance of the p-side electrode 21p and the n-side electrode 22n may increase.

### Solar Cell 1a Manufacturing Method

Next, one example of a manufacturing method of the solar cell 1a will be given.

First, the photoelectric converter 10 is prepared. Next, the p-side seed layer 17 is formed on the p-type surface 10bp and the n-side seed layer 18 is formed on the n-type surface 10bn. The p-side seed layer 17 and the n-side seed layer 18 may be continuously formed by, for example, a sputtering or CVD method, and the region defined by the width W₂ may be formed by separating the p-side seed layer 17 and the n-side seed layer 18 by, for example, a photolithography method.

Next, the insulating layer 23 is formed. More specifically, the insulating layer 23 is formed above the boundary between the p-type surface 10bp and the n-type surface 10bn of the back surface 10b of the photoelectric converter 10 so that the exposed region of the p-type surface 10bp and the exposed region of the n-type surface 10bn are separated from one other. The formation method of the insulating layer 23 is not particularly limited to a certain method. For example, when the insulating layer 23 includes an organic insulating material, the insulating layer 23 may be formed by a screen printing, ink jet, dispenser, or photolithography method, for example.

Next, the p-side electrode 21p is formed on the p-type surface 10bp and the n-side electrode 22n is formed on the n-type surface 10bn by a plating method such as electrolytic plating. Here, in order to keep the p-side electrode 21p and the n-side electrode 22n from coming into contact with one another on the insulating layer 23, the insulating layer 23 is preferably formed from, for example, a photoresist, which can be formed with a high degree of accuracy.

### Embodiment 2

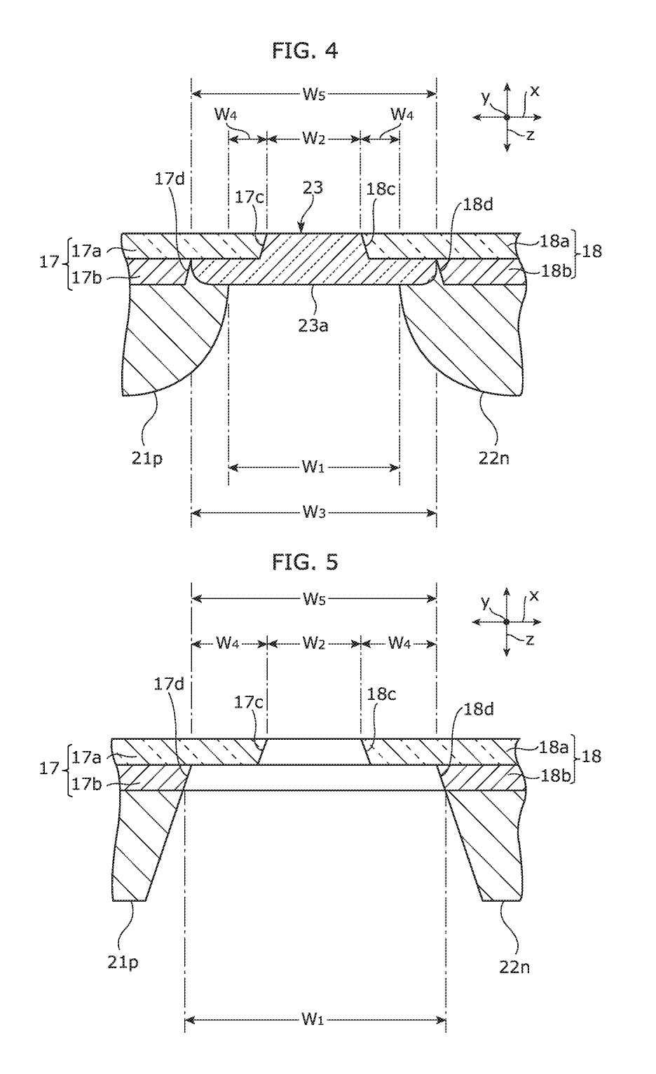

FIG. 4 is an enlarged schematic cross sectional view of the vicinity of the insulating layer in the solar cell according to Embodiment 2. In this embodiment, the transparent conducting layer 17a, transparent conducting layer 18a, metal layer 17b, and metal layer 18b are formed such that the width W₅ between the end 17d of the metal layer 17b and the end 18d of the metal layer 18b is greater than the width W₂ between the end 17c of the transparent conducting layer 17a and the end 18c of the transparent conducting layer 18a. Thus, the width W₅ between the p-side seed layer 17 and the n-side seed layer 18 that are adjacent to one another is greater than the width W₂ between the p-side seed layer 17 and the n-side seed layer 18 that are adjacent to one another.

In this embodiment, the end 17d is recessed from the end 17c, and the end 18d is recessed from the end 18c. The metal layer 17b and metal layer 18b exhibiting such a positional relationship may be formed by, for example, first forming the transparent conducting layer 17a, transparent conducting layer 18a, metal layer 17b, and metal layer 18b, and then selectively etching the ends of the metal layer 17b and the metal layer 18b, similar to Embodiment 1.

The head 23a of the insulating layer 23 extends so as to cover the end 17c of the transparent conducting layer 17a and the end 18c of the transparent conducting layer 18a. The p-side electrode 21p is disposed on the p-side seed layer 17. The n-side electrode 22n is disposed on the n-side seed layer 18. The p-side electrode 21p is formed so as to cover a portion of the head 23a of the insulating layer 23. The n-side electrode 22n is also formed so as to cover a portion of the head 23a of the insulating layer 23. Thus, the head 23a of the insulating layer 23 is embedded between the transparent conducting layer 17a and the p-side electrode 21p as well as between the transparent conducting layer 18a and the n-side electrode 22n. Note that the head 23a of the insulating layer 23 may be formed such that the x axis ends of the head 23a cover the end 17d and the end 18d.

The p-side seed layer 17 and the n-side seed layer 18 according to Embodiment 2 may be formed by the following method, for example. First, the p-side seed layer 17 and the n-side seed layer 18 are continuously formed by a sputtering or CVD method, for example. Next, the region defined by the width W₅ between the metal layer 17b and the metal layer 18b is formed by separating the metal layer 17b and the metal layer 18b by, for example, an etching method. Finally, the region defined by the width W₂ between the transparent conducting layer 17a and the transparent conducting layer 18a is formed by separating the transparent conducting layer 17a and the transparent conducting layer 18a by, for example, an etching method.

In this embodiment, the insulating layer 23 includes a transparent insulating material. Examples of the transparent insulating material include a transparent organic insulating material, and a transparent resist material.

In this embodiment as well, the width W₁ between the two closest points of the p-side electrode 21p and the n-side electrode 22n that are adjacent to one another is greater than the width W₂ between the two closes points of the end of the p-side seed layer 17 and the end of the n-side seed layer 18 that are adjacent one another. Thus, the width W₂ can be made to be relatively narrower than the width W₁. As a result, the surface area of the p-side seed layer 17 and the n-side seed layer 18 in the solar cell 1a can be made to be relatively larger, whereby collection efficiency can be increased.

In this embodiment, the insulating layer 23 includes a transparent insulating material. As such, the area defined by the width W₂ can absorb light. Furthermore, in the regions W₄, the transparent insulating layer 23 is formed on the transparent conducting layer 17a and the transparent conducting layer 18a. As such, the region W₄ can also absorb light. Thus, in this embodiment, light can be let in from the back surface as well, thereby increasing the amount of power generation.

### Embodiment 3

FIG. 5 is an enlarged schematic cross sectional view of the vicinity of the insulating layer in the solar cell according to Embodiment 3. In this embodiment, the transparent conducting layer 17a, transparent conducting layer 18a, metal layer 17b, and metal layer 18b are formed such that the width W₅ between the end 17d of the metal layer 17b and the end 18d of the metal layer 18b is greater than the width W₂ between the end 17c of the transparent conducting layer 17a and the end 18c of the transparent conducting layer 18a. The relationship between the width W₂ and the width W₅ is the same as in Embodiment 2.

In this embodiment, the insulating layer 23 is omitted. The solar cell 1 according to this embodiment can be manufactured as follows. Similar to Embodiments 1 and 2, the p-side seed layer 17 and the n-side seed layer 18 are continuously formed by a sputtering or CVD method, for example. Next, in this embodiment, a plating film is formed by a plating method, such as electrolytic plating, on the entire surfaces of the continuously formed p-side seed layer 17 and n-side seed layer 18. Then, a resist mask is formed in regions other than the region defined by the width W₁ illustrated in FIG. 5. Next, the regions left exposed by the resist mask—that is to say, the plating film, metal layer 17b and metal layer 18b formed on the entire surface of the region defined by the width W₁—are removed by etching. Here, the etching liquid used is one whose etching rate is slower with respect to the transparent conducting layer 17a and the transparent conducting layer 18a.

In this way, the plating film, metal layer 17b, and metal layer 18b in the region defined by the width W₁ are removed. Next, a resist mask is formed on regions of the transparent conducting layer 17a and the transparent conducting layer 18a exposed by the removal of the metal layer 17b and the metal layer 18b and not in the region defined by the width W₂, and the regions of the transparent conducting layer 17a and the transparent conducting layer 18a defined by the width W₂ are removed by etching with, for example, hydrochloric acid.

The metal layer 17b and the metal layer 18b formed as described above, as well as the transparent conducting layer 17a and the transparent conducting layer 18a are formed without providing the insulating layer 23.

The solar cell according to this embodiment can be manufactured as described above.

In this embodiment as well, since the width W₁ is greater than the width W₂, the width W₂ can be made to be relatively narrower than the width W₁, whereby collection efficiency can be increased.

Moreover, in this embodiment, the insulating layer 23 is omitted. As such, similar to Embodiment 2, the area defined by the width W₂ can absorb light. Furthermore, the region W₄ can also absorb light. Thus, similar to Embodiment 2, in this embodiment as well, light can be let in from the back surface as well, thereby increasing the amount of power generation.

Note that in the configuration exemplified in Embodiment 3, the insulating layer 23 is omitted, but the configuration may include the insulating layer 23. When included, the insulating layer 23 has a function of a film that protects the areas where the p-side seed layer 17 and the n-side seed layer 18 are not formed (i.e., the areas defined by width W₁ and width W₂). With provision of the insulating layer 23, the power generating region (the photoelectric converter 10 including the semiconductor layer 14p and the semiconductor layer 15n) can be protected from the surrounding environment of the solar cell to further increase reliability. Moreover, there are instances where internal stress generates after the formation of the electrode layers such as the p-side electrode 21p and the n-side electrode 22n that can cause the substrate to bow and crack, for example, in the vicinity of the region defined by the width W₁, which is the region that separates the electrodes. Providing the insulating layer 23 can inhibit this problem. In particular, by making the insulating layer 23 have essentially the same internal stress characteristics in terms of polarity (contraction or expansion) and magnitude as the p-side electrode 21p and the n-side electrode 22n, stress locally imparted on the substrate is alleviated, whereby the mechanical reliability of the solar cell can be further increased.

In each of the above embodiments, the substrate 11 is exemplified as having an n-type conductivity, but the substrate 11 may have a p-type conductivity.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell, comprising:
a photoelectric converter having a p-type surface on a major surface and an n-type surface on the major surface;
a p-side electrode disposed on the p-type surface and formed from a plating film;
an n-side electrode disposed on the n-type surface and formed from a plating film;
a p-side seed layer disposed between the p-type surface and the p-side electrode; and
an n-side seed layer disposed between the n-type surface and the n-side electrode,
wherein a width W₁ between two closest points of the p-side electrode and the n-side electrode that are adjacent one another is greater than a width W₂ between two closest points of an end of the p-side seed layer and an end of the n-side seed layer that are adjacent one another.

2. The solar cell according to claim 1, wherein
the p-side electrode and the n-side electrode each include a plurality of finger electrodes, and
the plurality of finger electrodes included in the p-side electrode and the plurality of finger electrodes included in the n-side electrode are interdigitated.

3. The solar cell according to claim 2, further comprising an insulating layer between the end of the p-side seed layer and the end of the n-side seed layer that are adjacent one another, the insulating layer having a head extending in an extending direction and covering the end of the p-side seed layer and the end of the n-side seed layer.

4. The solar cell according to claim 3, wherein a width W₃ of the head in the extending direction is at least two times the width W₂.

5. The solar cell according to claim 1, wherein the p-side seed layer and the n-side seed layer each include a transparent conducting layer and a metal layer on the transparent conducting layer, the transparent conducting layer included in the p-side seed layer being disposed on the p-type surface, and the transparent conducting layer included in the n-side seed layer being disposed on the n-type surface.

6. The solar cell according to claim 5, wherein in the p-side seed layer and the n-side seed layer that are adjacent one another, a width between the metal layer included in the p-side seed layer and the metal layer included in the n-side seed layer is greater than (i) a width between the transparent conducting layer included in the p-side seed layer and the transparent conducting layer included in the n-side seed layer, and (ii) the width W₂.

7. The solar cell according to claim 3, wherein the insulating layer is transparent.

8. The solar cell according to claim 3, wherein the insulating layer includes a resist material.

9. The solar cell according to claim 1, wherein the photoelectric converter includes:
a substrate including a semiconductor material;
a p-type amorphous silicon layer disposed on a major surface of the substrate and having the p-type surface; and
an n-type amorphous silicon layer disposed on the major surface of the substrate and having the n-type surface.

10. The solar cell according to claim 3, wherein, in substance, internal stress in the insulating layer and internal stress in each of the p-side seed layer, the n-side seed layer, the p-side electrode, and the n-side electrode are equal in polarity and substantially equal in magnitude.
